(19) United States
(12) Patent Application Publication
(10) Pub. No.: US 2012/0300380 A1
(43) Pub. Date: Nov. 29, 2012

(54) LAPTOP COMPUTER WITH MANUALLY OPERATED SWITCH FOR DIVERTING KEY CODES TO BLUETOOTH DEVICE COMMUNICATION MODULE

(75) Inventors: PEI-HSIN LIN, Ta Ya Shiang (TW); Yu-Wen Hsu, Ta Ya Shiang (TW); Chih-Shien Yao, Ta Ya Shiang (TW)

(73) Assignee: Sunrex Technology Corp., Ta Ya Shiang (TW)

(21) Appl. No.: 13/115,671

(22) Filed: May 25, 2011

(51) Int. Cl. H05K 7/02

(52) U.S. Cl. 361/679.09

(57) ABSTRACT

A laptop computer includes a housing comprising a top keyboard and a manually operated switch having a first position for showing a predetermined operating mode, and a second position for showing a Bluetooth operating mode; a display hingedly connected to a rear edge of the housing; a CPU in the housing; and a Bluetooth adaptor in the housing and comprising a switch circuit, a MCU, a translator, and a Bluetooth device communication module. In the predetermined operating mode key codes are sent to the CPU via the switch circuit. In the Bluetooth operating mode the key codes are sent to the translator via the switch circuit and the MCU, the translator translates the key codes to Bluetooth key codes and sends same to the Bluetooth device communication module, and the Bluetooth device communication module transmits the Bluetooth key codes to a handheld telecommunications device as commanded by the MCU.

### BACKGROUND OF THE INVENTION

1. Field of the Invention

The invention relates to laptop computers and more particularly to such a laptop computer having a manually operated switch on top for either diverting key codes to computer software in a default operating mode or diverting same to a Bluetooth device communication module which in turn, after receiving translated Bluetooth key codes, may transmit same to a handheld telecommunications device in a Bluetooth operating mode.

2. Description of Related Art

Universal Serial Bus (USB) is a specification to establish communication between devices and a host controller (e.g., a personal computer (PC)). USB can connect computer peripherals such as mice, keyboards, digital cameras, printers, personal media players, flash drives, and external hard drives. Unlike the older connection standards RS-232 or Parallel port, USB connectors also supply electric power, so many devices connected by USB do not need a power source of their own.

Bluetooth is a proprietary open wireless technology standard for exchanging data over short distances by using short wavelength radio transmissions from fixed and mobile devices, creating personal area networks (PANs) with high levels of security. It was originally conceived as a wireless alternative to RS-232 data cables. It can connect several devices, overcoming problems of synchronization. Bluetooth provides a secure way to connect and exchange information between devices such as faxes, mobile phones, telephones, laptop computers, PCs, Global Positioning System (GPS) receivers, digital cameras, and video game consoles.

Nowadays, mobile phones are capable of sending or receiving emails. However, a drawback of sending or receiving emails by using a mobile phone is that size of messages shown on LCD display thereof is relatively small. Moreover, keys of keypad of the mobile phone are small. Hence, a senior citizen or an individual with poor eyesight may have difficulties of entering information by typing on the keypad to send an email or reading a received email when using a mobile phone. In addition, it is prone to error. Thus, the need for improvement still exists.

### SUMMARY OF THE INVENTION

It is therefore one object of the invention to provide a laptop computer comprising a housing comprising a top keyboard including a plurality of keys for keying in and a manually operated switch having a first position for showing a predetermined operating mode, and a second position for showing a Bluetooth operating mode; a display hingedly connected to a rear edge of the housing; a central processing unit (CPU) disposed in the housing; and a Bluetooth adaptor disposed in the housing and comprising a switch circuit, a microcontroller unit (MCU), a translator, and a Bluetooth device communication module; wherein in the predetermined operating mode with the switch in the first position key codes are sent to the CPU via the switch circuit; and wherein in the Bluetooth operating mode with the switch in the second position the key codes are sent to the translator via the switch circuit and the MCU, the translator translates the key codes to Bluetooth key codes and sends same to the Bluetooth device communication module, and the Bluetooth device communication module transmits the Bluetooth key codes to a handheld telecommunications device as commanded by the MCU.

The above and other objects, features and advantages of the invention will become apparent from the following detailed description taken with the accompanying drawings.

### BRIEF DESCRIPTION OF THE DRAWINGS

FIG. 1 is a perspective view of a laptop computer according to the invention open for being ready to use;

FIG. 2 is a block diagram of the keyboard of the laptop computer;

FIG. 3 is a block diagram of a Bluetooth adaptor mounted in the keyboard of the laptop computer and other associated components of the laptop computer and a handheld telecommunications device;

FIG. 4 is a simplified block diagram of FIG. 3 showing a default operating mode of keying in; and

FIG. 5 is a simplified block diagram of FIG. 3 showing a Bluetooth operating mode of keying in.

### DETAILED DESCRIPTION OF THE INVENTION

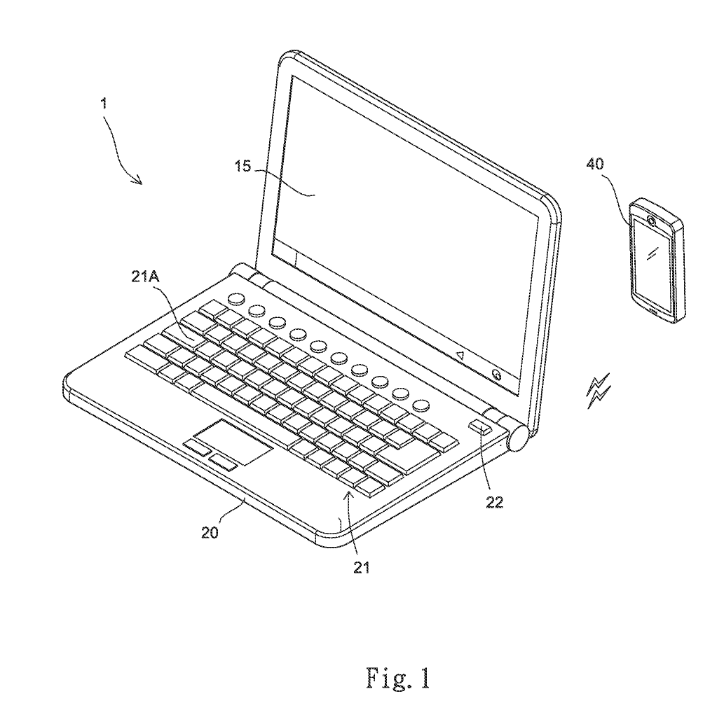

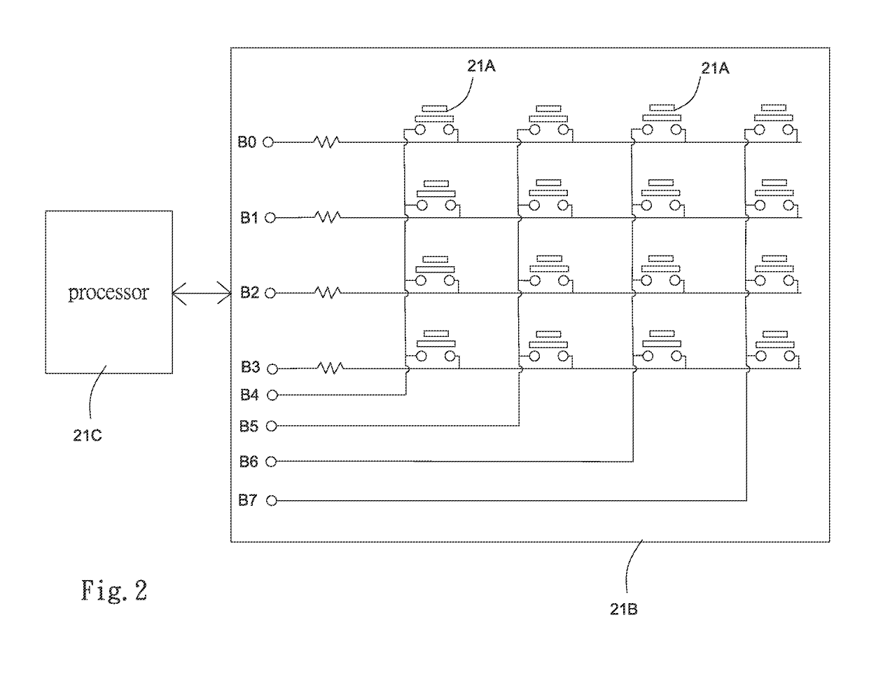

Referring to FIGS. 1 to 5, a laptop computer 1 in accordance with the invention comprises the following components as discussed in detail below.

A flat, rectangular housing 20 comprises a top keyboard 21 and a manually operated switch 22 on the right top corner of the housing 20. A central processing unit (CPU) 10 is vided on a mother board in the housing 20. A Bluetooth adaptor 30 is also provided on the mother board in the housing 20. A display (e.g., LCD (liquid crystal display) display) 15 is hingedly connected to a rear edge of the housing 20.

The keyboard 21 comprises a plurality of keys 21A arranged in a predetermined set, a key matrix module 21B including a plurality of key cells arranged in matrix, and a processor 21C electrically connected to the matrix key module 21B. The processor 21C may continuously read input signals on output ends B0 to B7 of the key cells in the matrix key module 21B by polling in response to depressing any key.

The switch 22 has a first position with an indicator for showing a default operating mode of keying in, and a second position with an indicator for showing a Bluetooth operating mode. A user may slide the lever of the switch 22 to either the first position or the second position as desired. Each indicator is provided with a light (e.g., LED (light-emitting diode)) (not shown) so as to visually indicate what the operating mode of the laptop computer 1 is.

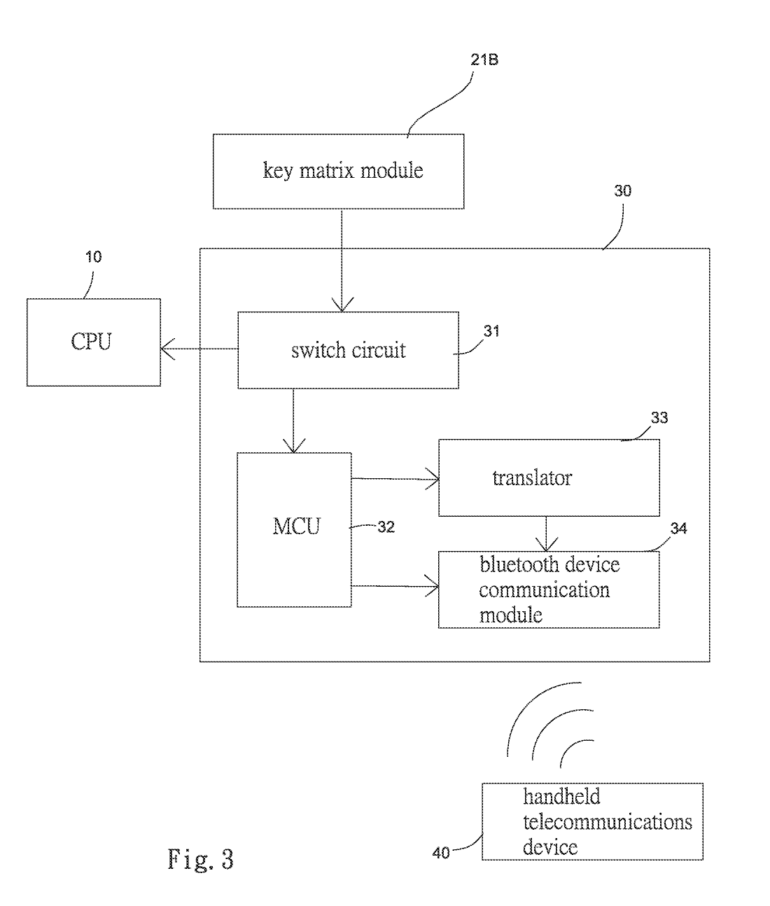

The Bluetooth adaptor 30 is implemented as a printed circuit board (PCB) and provided on the mother board in the housing 20. The Bluetooth adaptor 30 comprises a switch circuit 31 electrically connected to both the switch 22 and the key matrix module 21B, a MCU (microcontroller unit) 32, a translator 33, and a Bluetooth device communication module 34. Electrical connections of the components of the Bluetooth adaptor 30, the CPU 10, and the key matrix module 21B are indicated by arrow lines of FIG. 3.

The MCU 32 is a single chip and has circuitry. The MCU 32 is electrically interconnected the switch circuit 31 and the Bluetooth device communication module 34. The switch circuit 31 is electrically interconnected the key matrix module 21B and the MCU 32. The switch circuit 31 can function in response to different positions of the switch 22. The translator 33 is electrically interconnected the MCU 32 and the Bluetooth device communication module 34. The translator 33 can receive key codes sent from the key matrix module 21B via the switch circuit 31 and the MCU 32 when the switch 22 is in the second position. Further, the received key codes are translated to Bluetooth key codes by the translator 33 prior to sending to the Bluetooth device communication module 34. The Bluetooth device communication module 34 can transmit the Bluetooth key codes to the handheld telecommunications device (e.g., smartphone) 40 as commanded by the MCU 32.

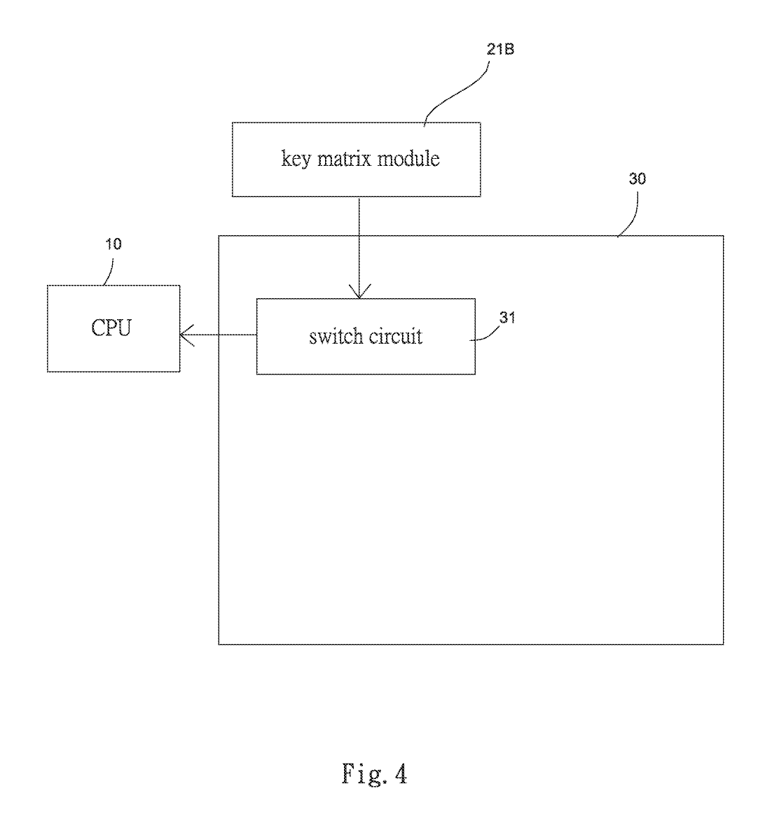

As shown in FIG. 4 specifically, there is shown a default operating mode of the laptop computer 1 when the switch 22 is in the first position. A user may enter information by typing on keys 21A. Key or command signals associated with the typed keys 21A are processed into key codes by the processor 21C in cooperation with the key matrix module 21B. And in turn, the key codes are sent from the key matrix module 21B to the CPU 10 for further processing by computer software via the switch circuit 31.

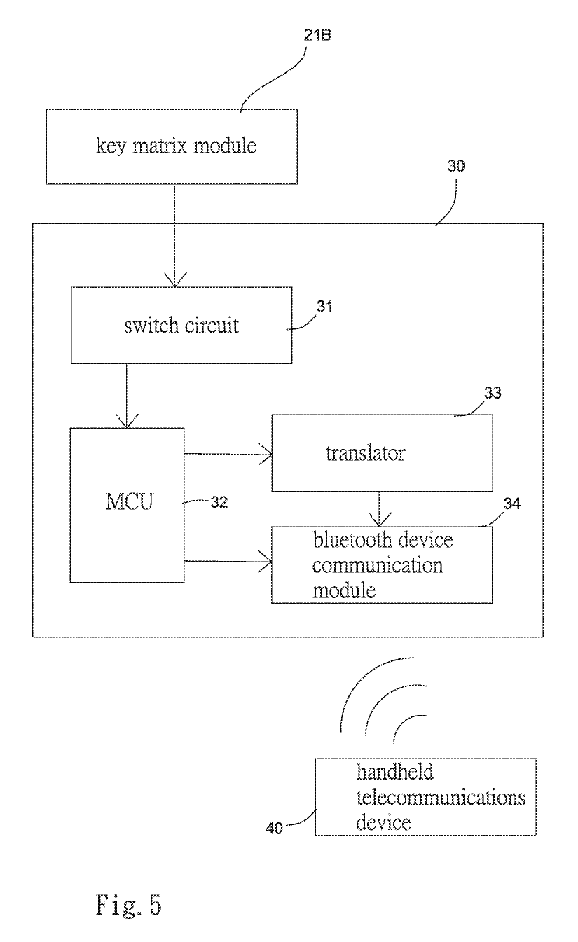

As shown in FIG. 5 specifically, there is shown a Bluetooth operating mode of the laptop computer 1 when the switch 22 is in the second position. A user may enter information by typing on keys 21A. Key or command signals associated with the typed keys 21A are processed into key codes by the processor 21C in cooperation with the key matrix module 21B. And in turn, the key codes are sent from the key matrix module 21B to the translator 33 via the switch circuit 31 and the MCU 32. The received key codes are translated to Bluetooth key codes by the translator 33 prior to sending to the Bluetooth device communication module 34. Finally, the Bluetooth device communication module 34 transmits the Bluetooth key codes to the handheld telecommunications device (e.g., smartphone) 40 as commanded by the MCU 32.

It is envisaged by the invention that a user may use the large LCD display 15 and the keyboard 21 of the laptop computer 1 to key in a message to be sent to a handheld telecommunications device (e.g., smartphone) 40 by emailing or view contents of a received email on the LCD display 15. This is beneficial to senior citizens and individuals with poor eyesight.

While the invention has been described in terms of preferred embodiments, those skilled in the art will recognize that the invention can be practiced with modifications within the spirit and scope of the appended claims.

What is claimed is:

1. A laptop computer comprising:
a housing comprising a top keyboard including a plurality of keys for keying in and a manually operated switch having a first position for showing a predetermined operating mode, and a second position for showing a Bluetooth operating mode;
a display hingedly connected to a rear edge of the housing;
a central processing unit (CPU) disposed in the housing; and
a Bluetooth adaptor disposed in the housing and comprising a switch circuit, a microcontroller unit (MCU), a translator, and a Bluetooth device communication module;
wherein in the predetermined operating mode with the switch in the first position key codes are sent to the CPU via the switch circuit; and
wherein in the Bluetooth operating mode with the switch in the second position the key codes are sent to the translator via the switch circuit and the MCU, the translator translates the key codes to Bluetooth key codes and sends same to the Bluetooth device communication module, and the Bluetooth device communication module transmits the Bluetooth key codes to a handheld telecommunications device as commanded by the MCU.

2. The laptop computer of claim 1, wherein the keyboard comprises the plurality of keys, a key matrix module including a plurality of key cells arranged in matrix, and a processor for continuously reading input signals of the key cells by polling in response to depressing of the key.

3. The laptop computer of claim 2, wherein the switch circuit is electrically interconnected the key matrix module and the MCU so that the switch circuit functions in response to either the first position or the second position of the switch.

4. The laptop computer of claim 1, wherein the MCU is a single chip and has circuitry, and wherein the MCU is electrically interconnected the switch circuit and the Bluetooth device communication module.

5. The laptop computer of claim 1, wherein the translator is electrically interconnected the MCU and the Bluetooth device communication module.

6. The laptop computer of claim 1, wherein the handheld telecommunications device is a smartphone.

7. The laptop computer of claim 1, furthering comprising two indicators each corresponding to either the first position or the second position for visually indicating that the switch is in either the first position or the second position.

8. The laptop computer of claim 7, wherein the indicators are light-emitting diodes (LEDs).
